(19) United States
(12) Patent Application Publication
(10) Pub. No.: US 2024/0008192 A1
(43) Pub. Date: Jan. 4, 2024

(54) DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yun DENG, Wuhan, Hubei (CN)

(21) Appl. No.: 17/790,163

(22) PCT Filed: Jun. 29, 2022
(86) PCT No.: PCT/CN2022/102160

§ 371 Date: Jun. 30, 2022

(51) Int. Cl. H05K 5/00

(52) U.S. Cl. CPC H05K 5/0018

(57) ABSTRACT

Disclosed in the present application is a display device. The display device includes a display panel, a backplate, and a composite support layer; the backplate is disposed on one side of the display panel; the composite support layer is disposed on one side of the backplate away from the display panel, the composite support layer includes a rigid support sub-layer and a flexible support sub-layer which are sequentially laminated; wherein a material of the rigid support sub-layer comprises polymethyl methacrylate, and a material of the flexible support sub-layer comprises polycarbonate.

### FIELD OF DISCLOSURE

The present disclosure relates to a field of display technology, and more specifically, to a display device.

### BACKGROUND

In recent years, consumers' requirements for appearances of display devices, such as mobile phones, televisions, and notebooks, have mainly focused on large-size, lightness and thinness, and borderless, etc. In order to meet needs of the consumers, many companies are also designing and developing the display devices in terms of lightness and thinness.

In a flexible display screen, stainless steel (SUS) material is usually disposed underneath a polyimide (PI) backplate. SUS material has characteristics of high hardness and high modulus, making it serve a supporting function for the flexible display screen. With diversified development of the flexible display screen, screen size has increased, and new display components are added to achieve diversified display function requirements. Changes to these components lead to a greater increase in a weight of the flexible display screen, which in turn lead to an increasing demand for weight reduction of the flexible display screen. In the flexible display screen, a commonly used support material is metal, resulting in the support material accounting for 40% of total weight of the flexible display screen. Therefore, it is particularly important to reduce weight of the support material.

### SUMMARY

Embodiments of the present application are to provide a display device, which can reduce a weight of the display device, maintain support for a display panel, and increase flexibility of the display device.

An embodiment of the present application provides a display device, the display device includes:
a display panel;
a backplate disposed on one side of the display panel;
a composite support layer disposed on one side of the backplate away from the display panel, the composite support layer including a rigid support sub-layer and a flexible support sub-layer sequentially laminated;
wherein a material of the rigid support sub-layer includes polymethyl methacrylate, and a material of the flexible support sub-layer includes polycarbonate.

In an embodiment of the present application, an elastic modulus of the rigid support sub-layer is greater than an elastic modulus of the flexible support sub-layer.

In an embodiment of the present application, the display device further includes a bending region, and the composite support layer further includes a plurality of openings defined in the bending region.

In an embodiment of the present application, the openings penetrate at least one of the rigid support sub-layer and the flexible support sub-layer.

In an embodiment of the present application, the plurality of the openings include first openings defined in the rigid support sub-layer and second openings defined in the flexible support sub-layer, and the first openings and the second openings are arranged in alignment or staggered.

In an embodiment of the present application, each of the openings extends along a first direction and is distributed in the bending region in an elongated shape, wherein the display device further includes a non-bending region adjacent to the bending region, and an included angle between the first direction and a direction of the bending region pointing to the non-bending region is greater than or equal to 0° and less than or equal to 90°.

In an embodiment of the present application, the composite support layer further includes a plurality of opening groups arranged along a second direction, and each of the opening groups includes the plurality of the openings arranged along the first direction, the second direction is perpendicular to the first direction, and the openings in one of the opening groups are arranged in a staggered manner with the openings in an adjacent one of the opening groups.

In an embodiment of the present application, the display device further includes a light-transmitting region, and a photosensitive device disposed in the light-transmitting region, the photosensitive device is disposed on one side of the composite support layer away from the backplate, and an orthographic projection of the photosensitive device on the backplate is located within a coverage of an orthographic projection of the composite support layer on the backplate.

In an embodiment of the present application, a phase difference of the composite support layer is less than or equal to 50 nm, and a light transmittance rate of the composite support layer is greater than or equal to 90%.

In an embodiment of the present application, the composite support layer further includes a first metal shielding film disposed on one side of the rigid support sub-layer away from the flexible support sub-layer, and a second metal shielding film disposed on one side of the flexible support sub-layer away from the rigid support sub-layer, wherein the first metal shielding film and the second metal shielding film are both defined with first light-transmitting holes in the light-transmitting region.

In an embodiment of the present application, the composite support layer further includes a first light-shielding film disposed on one side of the rigid support sub-layer away from the flexible support sub-layer, and a second light-shielding film disposed on one side of the flexible support sub-layer away from the rigid support sub-layer, wherein the first light-shielding film and the second light-shielding film are both defined with second light-transmitting holes in the light-transmitting region.

In an embodiment of the present application, a material of the first light-shielding film and a material of the second light-shielding film both have conductivity.

In an embodiment of the present application, the rigid support sub-layer is located between the flexible support sub-layer and the backplate, and a ratio of a thickness of the flexible support sub-layer to a thickness of the rigid support sub-layer is greater than or equal to 3:2 and less than or equal to 4:1.

According to the foregoing objective of the present application, the present application also provides a display device, the display device includes:
a display panel;
a backplate disposed on one side of the display panel;
a composite support layer disposed on one side of the backplate away from the display panel, the composite support layer including a rigid support sub-layer and a flexible support sub-layer sequentially laminated, and an elastic modulus of the rigid support sub-layer being greater than an elastic modulus of the flexible support sub-layer;
wherein a material of the rigid support sub-layer includes polymethyl methacrylate, and a material of the flexible support sub-layer includes polycarbonate.

In an embodiment of the present application, the display device further includes a bending region, and the composite support layer further includes a plurality of openings defined in the bending region.

In an embodiment of the present application, the display device further includes a light-transmitting region and a photosensitive device disposed in the light-transmitting region, the photosensitive device is disposed on one side of the composite support layer away from the backplate, and an orthographic projection of the photosensitive device on the backplate is located within a coverage of an orthographic projection of the composite support layer on the backplate.

In an embodiment of the present application, a phase difference of the composite support layer is less than or equal to 50 nm, and a light transmittance rate of the composite support layer is greater than or equal to 90%.

In an embodiment of the present application, the composite support layer further includes a first metal shielding film disposed on one side of the rigid support sub-layer away from the flexible support sub-layer, and a second metal shielding film disposed on one side of the flexible support sub-layer away from the rigid support sub-layer, wherein the first metal shielding film and the second metal shielding film are both defined with first light-transmitting holes in the light-transmitting region.

In an embodiment of the present application, the composite support layer further includes a first light-shielding film disposed on one side of the rigid support sub-layer away from the flexible support sub-layer, and a second light-shielding film disposed on one side of the flexible support sub-layer away from the rigid support sub-layer, wherein the first light-shielding film and the second light-shielding film are both defined with second light-transmitting holes in the light-transmitting region.

In an embodiment of the present application, a material of the first light-shielding film and a material of the second light-shielding film both have conductivity.

### Advantages of the Present Disclosure

Compared with the prior art, the present application uses the rigid support sub-layer and the flexible support sub-layer which are sequentially laminated as the composite support layer, wherein the material of the rigid support sub-layer includes polymethyl methacrylate, and the material of the flexible support sub-layer includes polycarbonate, and the elastic modulus of polymethyl methacrylate is greater than the elastic modulus of polycarbonate, so that the rigid support sub-layer has a certain hardness, and the flexible support sub-layer has a certain flexibility, thereby improving flexibility and bending performance of the display device while making it serve a supporting function for the display device. In addition, due to low density of polymethyl methacrylate and polycarbonate, a weight of the composite support layer is very light, thus effectively reducing weight of the display device.

### BRIEF DESCRIPTION OF DRAWINGS

Technical solutions and other beneficial effects of the present application will be apparent from the following detailed description of specific implementations of the present application with reference to accompanying drawings.

FIG. 1 is a schematic structural diagram of a display device provided by an embodiment of the present application.

FIG. 2 is a schematic structural diagram of a plane distribution of a composite support layer provided by an embodiment of the present application.

FIG. 3 is a schematic view of size of openings in the composite support layer provided by an embodiment of the present application.

FIG. 4 is a schematic structural diagram of the openings in the composite support layer provided by an embodiment of the present application.

FIG. 5 is another schematic structural diagram of the openings in the composite support layer provided by an embodiment of the present application.

FIG. 6 is a schematic structural diagram of a corresponding bending region of the composite support layer provided by an embodiment of the present application.

FIG. 7 is a schematic structural diagram of the composite support layer provided by an embodiment of the present application.

FIG. 8 is another schematic structural diagram of the corresponding bending region of the composite support layer provided by an embodiment of the present application.

FIG. 9 is another schematic structural diagram of the composite support layer provided by the embodiment of the present application.

### DETAILED DESCRIPTION

Technical solutions in embodiments of the present application are clearly described in the following with reference to the accompanying drawings. Apparently, embodiments to be described are merely a part rather than all of the embodiments of the present application. All other embodiments obtained by persons of ordinary skill in the art based on the embodiments of the present application without creative efforts shall fall within the protection scope of the present application.

The following disclosure provides many different embodiments or examples for implementing different structures of the present application. In order to simplify the disclosure of the present application, the components and arrangements of the specific examples are described below. Certainly, they are merely examples and are not intended to limit the present application. In addition, the present application may be repeated with reference numerals and/or reference letters in the different examples, which are for the purpose of simplicity and clarity, and do not indicate the relationship between the various embodiments and/or arrangements discussed. Moreover, the present application provides examples of various specific processes and materials, but one of ordinary skill in the art will recognize that other processes and/or the use of other materials can be used.

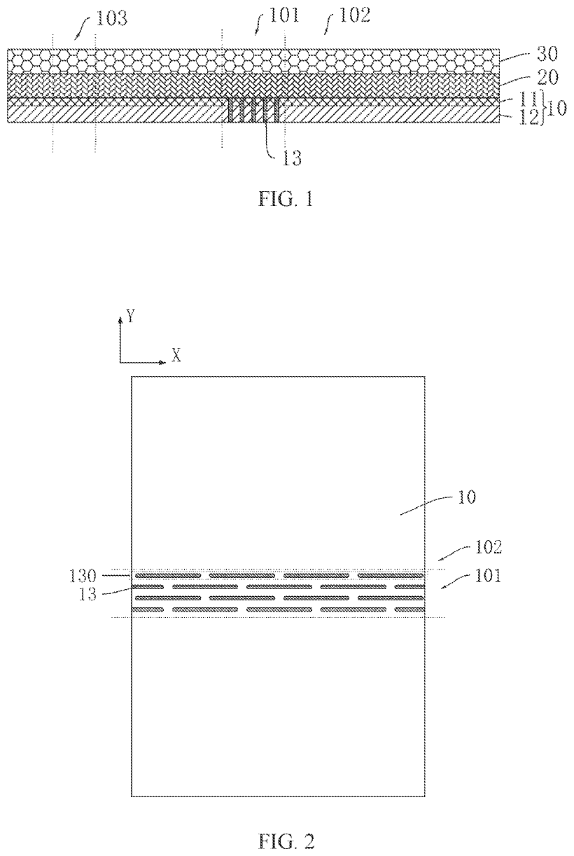

An embodiment of the present application provides a display device. Please refer to FIG. 1. The display device includes a display panel 30, a backplate 20, and a composite support layer 10.

The backplate 20 is disposed on one side of the display panel 30. The composite support layer 10 is disposed on one side of the backplate 20 away from the display panel 30, and the composite support layer 10 includes a rigid support sub-layer 11 and a flexible support sub-layer 12 which are sequentially laminated.

Further, a material of the rigid support sub-layer 11 includes polymethyl methacrylate, and a material of the flexible support sub-layer 12 includes polycarbonate.

In an implementation of an application, an existing support material is mainly stainless steel, titanium alloy, and carbon fiber material, etc., wherein a density of stainless steel is 7.7-7.9 g/cm³, a density of titanium alloy is 4.51 g/cm³, and a density of carbon fiber material is 1.5-1.8 g/cm³. Further, a density of conventional glass material is 2.4-2.8 g/cm³. However, in an embodiment of the present application, the rigid support sub-layer 11 and the flexible support sub-layer 12 which are sequentially laminated are used as the composite support layer 10 to be disposed on the one side of the backplate 20 away from the display panel 30, wherein the material of the rigid support sub-layer 11 includes polymethyl methacrylate, the material of the flexible support sub-layer 12 includes polycarbonate, and an elastic modulus of the rigid support sub-layer is greater than an elastic modulus of the flexible support sub-layer, so that the rigid support sub-layer has a certain hardness, the flexible support sub-layer has a certain flexibility, and thus the rigid support sub-layer 11 can serve a good supporting function for the backplate 20 and the display panel 30, while the flexible support sub-layer 12 can improve flexibility of the display device so as to improve bending performance of the display device. Further, a density of the polymethyl methacrylate and a density of the polycarbonate are both very small and less than the density of stainless steel, the density of titanium alloy, and the density of carbon fiber material, etc., so that a density of the composite support layer 10 may be 1.15-1.19 g/cm³, thereby effectively reducing weight of the composite support layer 10 and realizing weight reduction of the display device.

Specifically, in an embodiment of the present application, please refer to FIG. 1, the display device provided by the embodiment of the present application includes a bending region 101, and a non-bending region 102 adjacent to the bending region 101, and the display device further includes the display panel 30, the backplate 20, and the composite support layer 10, wherein the backplate 20 is disposed on a back side of the display panel 30, which is a side of the display panel 30 away from a display surface, and the composite support layer 10 is disposed on the one side of the backplate 20 away from the display panel 30.

Wherein the composite support layer 10 includes the rigid support sub-layer 11 and the flexible support sub-layer 12 which are sequentially laminated, and the elastic modulus of the rigid support sub-layer 11 is greater than the elastic modulus of the flexible support sub-layer 12. The rigid support sub-layer 11 can serve a good supporting function for the backplate 20 and the display panel 30, and the flexible support sub-layer 12 can improve the flexibility of the display device so as to improve the bending performance of the display device.

Preferably, the rigid support sub-layer 11 is disposed between the flexible support sub-layer 12 and the backplate 20. The rigid support sub-layer 11 is in direct contact with the side of the backplate 20 away from the display panel 30 and can serve a better supporting function for the backplate 20 and the display panel 30, and the rigid support sub-layer 11 is disposed between the backplate 20 and the flexible support sub-layer 12, so that it can serve a supporting function for film layers on both sides of the rigid support sub-layer 11, that is, can serve a supporting function for a whole display device.

In the embodiment of the present application, a thickness of the rigid support sub-layer 11 is less than a thickness of the flexible support sub-layer 12. Optionally, the ratio of the thickness of the flexible support sub-layer 12 to the thickness of the rigid support sub-layer 11 is greater than or equal to 3:2, and less than or equal to 4:1, and a thickness of the composite support layer 10 is greater than or equal to 0.2 mm, and less than or equal to 0.25 mm.

In the embodiment of the present application, since the rigid support sub-layer 11 is made of polymethyl methacrylate and the flexible support sub-layer 12 is made of polycarbonate, a finally formed composite support layer 10 has characteristics of high transparency and smooth surface, i.e., a light transmittance rate of the composite support layer 10 is greater than or equal to 90%, and a phase difference of the composite support layer 10 is less than or equal to 50 nm, which can effectively avoid a large in-plane phase difference resulting in occurrences of rainbow patterns.

Further, the display device provided in the embodiment of the present application further includes a light-transmitting region 103, and a photosensitive device (not shown in the drawings) disposed in the light-transmitting region 103. The photosensitive device is disposed on one side of the composite support layer 10 away from the backplate 20, and an orthographic projection of the photosensitive device on the backplate 20 is located within a coverage of an orthographic projection of the composite support layer 10 on the backplate 20, i.e., the composite support layer 10 does not need to be apertured at a position corresponding to the light-transmitting region 103. In contrast, the support material in the prior art requires an opening corresponding to an under-screen camera, and then after the support material is laminated to a panel body, it is easy to produce dent defects at a location of the opening. In the embodiment of the present application, since the composite support layer 10 has characteristics of high light transmittance rate and low phase difference, it can meet light input requirements of the photosensitive device and can also avoid a phenomenon of dent defect in the light-transmitting region 103, and there are no rainbow patterns.

Optionally, the photosensitive device may be a camera.

It should be noted that, in the display device provided by the embodiment of the present application, the light-transmitting region 103 may be located in the non-bending region 102 or the bending region 101, and in the embodiment of the present application, the light-transmitting region 103 located in the non-bending region 102 as an example will be described.

In the embodiment of the present application, the composite support layer 10 further includes a plurality of openings 13 defined in the bending region 101, and a depth of the openings 13 is less than or equal to the thickness of the composite support layer 10; i.e., the openings 13 may pass through part of the rigid support sub-layer 11, or all of the rigid support sub-layer 11, or part of the flexible support sub-layer 12, or all of the flexible support sub-layer 12, or all of the rigid support sub-layer 11 and part of the flexible support sub-layer 12, or part of the rigid support sub-layer 11 and all of the flexible support sub-layer 12, or all of the rigid support sub-layer 11 and all of the flexible support sub-layer 12. In the embodiment of the present application, the depth of the openings 13 is equal to the thickness of the composite support layer 10 as an example, i.e., the openings 13 pass through all of the rigid support sub-layers 11 and all of the flexible support sub-layers 12 as an example will be described.

In this embodiment of the present application, a plurality of openings 13 are defined at positions corresponding to the bending region 101 of the composite support layer to further improve the bending performance of the composite support layer 10, that is, to further improve the bending performance of the display device.

As mentioned above, in another embodiment of the present application, when the light-transmitting region 103 is located in the bending region 101, the composite support layer 10 is located in the light-transmitting region 103 with a plurality of openings 13, thereby further improving light transmittance rate of the light-transmitting region 103, improving light input amount of the photosensitive device disposed in the light-transmitting region 103, and improving photosensitive effect of the photosensitive device on a basis of an improvement in bending performance of the display device.

Please refer to FIG. 1 and FIG. 2 together, in the embodiment of the present application, each opening 13 extends along a first direction X and is distributed in the bending region 101 in an elongated shape, and a direction of the bending region 101 pointing to the non-bending region 102 is set as a second direction Y, wherein an included angle between the first direction X and the second direction Y may be greater than or equal to 0° and less than or equal to 90°. In the embodiment of the present application, the angle between the first direction X and the second direction Y is 90° as an example, that is, the first direction X and the second direction Y perpendicular to each other as an example will be described.

Further, the plurality of openings 13 may be distributed into a plurality of opening groups 130 defined in the bending region 101, and the plurality of opening groups 130 are arranged along the second direction Y. Each of the opening groups 130 includes the plurality of openings 13 arranged in the direction X, and the openings 13 in one of the opening groups 130 and the openings 13 in an adjacent one of the opening groups 130 are arranged in a staggered manner, thereby preventing an uneven distribution of a support effect of the composite support layer 10 in the bending region 101 along the second direction Y due to an over-concentration of the openings 13 arranged along the second direction Y, which can improve the support effect of the composite support layer 10, at a same time, ensuring the support effect of the composite support layer 10.

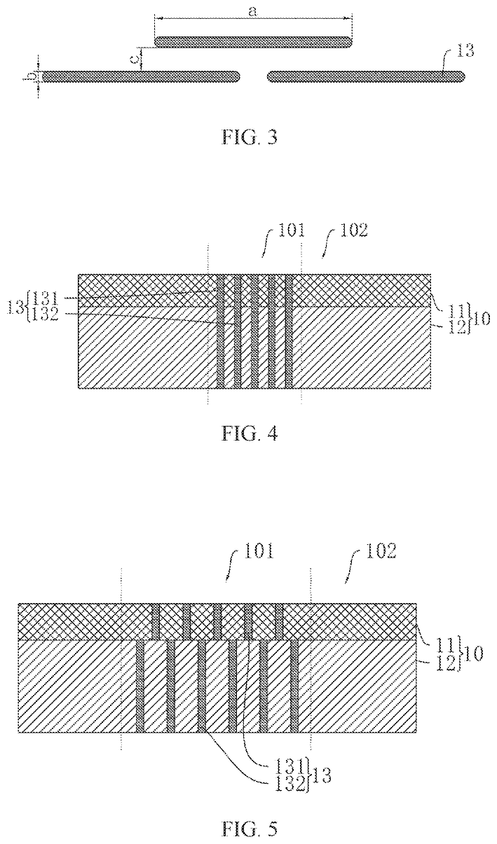

Please refer to FIG. 1, FIG. 2, and FIG. 3 together. Optionally, a hole length a of the openings 13 along the first direction X is greater than or equal to 6 mm and less than or equal to 8 mm, and a hole width b of the openings 13 along the second direction Y is greater than or equal to 0.15 mm and less than or equal to 0.2 mm, a hole spacing c along the second direction Y between two adjacent openings 13 along the second direction Y is greater than or equal to 0.1 mm and less than or equal to 0.15 mm.

In the embodiment of the present application, the plurality of openings 13 include first openings 131 defined in the rigid support sub-layer 11 and second openings 132 defined in the flexible support sub-layer 12, wherein each of the first openings 131 is arranged corresponding to one of the second openings 132, and the each of the first openings 131 is aligned and communicated with a corresponding one of the second openings 132, as shown in FIG. 4; or the plurality of first openings 131 and the plurality of second openings 132 are arranged in a staggered manner, as shown in FIG. 5; or part of the first openings 131 and part of the second openings 132 are aligned and communicated, while another part of the first openings 131 and another part of the second openings 132 are arranged in a staggered manner, which is not limited here, and can be selected according to actual needs.

As mentioned above, in the embodiment of the present application, the rigid support sub-layer 11 and the flexible support sub-layer 12 sequentially laminated are used as the composite support layer 10 to be disposed on the one side of the backplate 20 away from the display panel 30, wherein the rigid support sub-layer 11 can serve a good supporting function for the backplate 20 and the display panel 30, while the flexible support sub-layer 12 can improve flexibility of the display device so as to improve the bending performance of the display device. Further, the material of the rigid support sub-layer 11 includes polymethyl methacrylate, and the material of the flexible support sub-layer 12 includes polycarbonate. The density of polymethyl methacrylate and the density polycarbonate are both very small and less than the density of stainless steel, the density of titanium alloy, and the density of carbon fiber material, etc., thereby effectively reducing the weight of the composite support layer 10 and realizing weight reduction of the display device. Further, in the embodiment of the present application, openings 13 may be defined on a portion of the composite support layer 10 located in the bending region 101 to further improve the bending performance of the composite support layer 10, that is, to improve the bending performance of the display device.

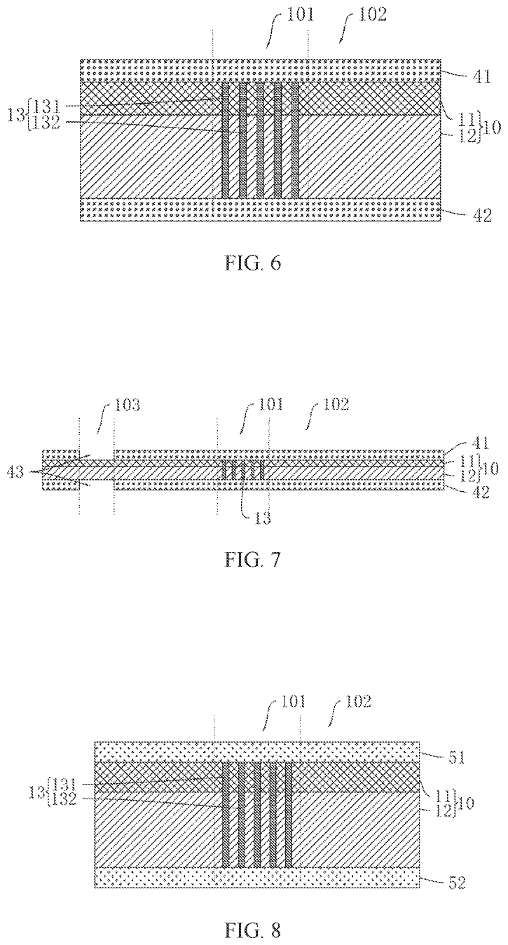

In another embodiment of the present application, please refer to FIG. 6 and FIG. 7, a difference between this embodiment and the previous embodiment is that multifunctionality of the composite support layer 10 is further enhanced.

In this embodiment, the composite support layer 10 includes a rigid support sub-layer 11 and a flexible support sub-layer 12 sequentially laminated. In addition, the composite support layer 10 further includes a first metal shielding film 41 disposed on one side of the rigid support sub-layer 11 away from the flexible support sub-layer 12, and a second metal shielding film 42 disposed on one side of the flexible support sub-layer 12 away from the rigid support sub-layer 11.

Optionally, a material of the first metal shielding film 41 and a material of the second metal shielding film 42 both include at least one of a metal and a metal oxide, so that when the composite support layer 10 is attached and used, it can serve a supporting function and improve flexibility while also providing electromagnetic shielding to improve stability and yield of the display device.

Further, in the embodiment of the present application, the display device further includes the light-transmitting region 103, and the photosensitive device (not shown in the drawings) disposed in the light-transmitting region 103, wherein the first metal shielding film 41 and the second metal shielding film 42 are defined with first light-transmitting holes 43 in the light-transmitting region 103, so as to improve light transmittance rate of the display device in the light-transmitting region 103.

As mentioned above, in the embodiment of the present application, the rigid support sub-layer 11 and the flexible support sub-layer 12 sequentially laminated are used as the composite support layer 10 to be disposed on the one side of the backplate 20 away from the display panel 30, wherein the rigid support sub-layer 11 can serve a good supporting function for the backplate 20 and the display panel 30, while the flexible support sub-layer 12 can improve the flexibility of the display device so as to improve the bending performance of the display device. Further, the material of the rigid support sub-layer 11 includes polymethyl methacrylate, the material of the flexible support sub-layer 12 includes polycarbonate, and the density of polymethyl methacrylate and the density of polycarbonate are both very small and less than the density of stainless steel, the density of titanium alloy, and the density of carbon fiber material, etc., thereby effectively reducing the weight of the composite support layer 10 and realizing weight reduction of the display device. Further, in the embodiment of the present application, openings 13 may be defined on the portion of the composite support layer 10 located in the bending region 101 to further improve the bending performance of the composite support layer 10, that is, to improve the bending performance of the display device. In addition, a metal shielding film may be disposed on the one side of the rigid support sub-layer 11 away from the flexible support sub-layer 12 and the on one side of the flexible support sub-layer 12 away from the rigid support sub-layer 11, so that the composite support layer 10 provided in the embodiment of the present application also has a function of electromagnetic shielding to improve a stability and yield of the display device.

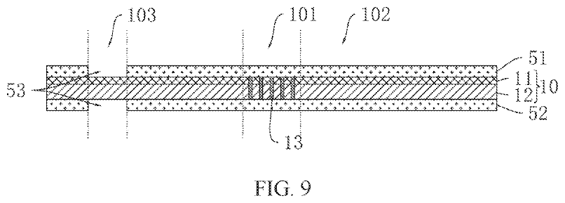

In another embodiment of the present application, please refer to FIG. 8 and FIG. 9, the difference between this embodiment and the first embodiment is that the multifunctionality of the composite support layer 10 is further enhanced.

In this embodiment, the composite support layer 10 includes the rigid support sub-layer 11 and the flexible support sub-layer 12 which are sequentially laminated. In addition, the composite support layer 10 further includes a first light-shielding film 51 disposed on the one side of the rigid support sub-layer 11 away from the flexible support sub-layer 12 and a second light-shielding film 52 disposed on the one side of the flexible support sub-layer 12 away from the rigid support sub-layer 11.

Optionally, the first light-shielding film 51 and the second light-shielding film 52 may be at least one of black ink and black glue formed on the rigid support sub-layer 11 and the flexible support sub-layer 12, respectively, and when the composite support layer 10 is attached and used, it can serve a supporting function and improve flexibility while serve a function of shielding light so as to prevent light leakage and ambient light from entering the display device, thereby improving display effect of the display device.

Further, in the embodiment of the present application, the display device further includes the light-transmitting region 103, and the photosensitive device (not shown in the drawings) disposed in the light-transmitting region 103, wherein the first light-shielding film 51 and the second light-shielding film 52 are defined with second light-transmitting holes 53 in the light-transmitting region 103 to improve the light transmittance rate of the display device in the light-transmitting region 103.

As mentioned above, in the embodiment of the present application, the rigid support sub-layer 11 and the flexible support sub-layer 12 sequentially laminated are used as the composite support layer 10 to be disposed on the one side of the backplate 20 away from the display panel 30, wherein the rigid support sub-layer 11 can serve a good supporting function for the backplate 20 and the display panel 30, while the flexible support sub-layer 12 can improve the flexibility of the display device so as to improve the bending performance of the display device. Further, the material of the rigid support sub-layer 11 includes polymethyl methacrylate, the material of the flexible support sub-layer 12 includes polycarbonate, the density of polymethyl methacrylate and the density of polycarbonate are both very small and less than the density of stainless steel, the density of titanium alloy, and the density of carbon fiber material, etc., thereby effectively reducing the weight of the composite support layer 10 and realizing weight reduction of the display device. Further, in the embodiment of the present application, the openings 13 may be defined on the portion of the composite support layer 10 located in the bending region 101 to further improve the bending performance of the composite support layer 10, that is, to improve the bending performance of the display device. In addition, a light-shielding film may be disposed on the one side of the rigid support sub-layer 11 away from the flexible support sub-layer 12 and on the one side of the flexible support sub-layer 12 away from the rigid support sub-layer 11, so that the composite support layer 10 provided in the embodiment of the present application also has the function of shielding light, thereby improving the display effect of the display device.

In another embodiment of the present application, please continue to refer to FIG. 8 and FIG. 9, the difference between this embodiment and the previous embodiment is that the material of the first light-shielding film 51 and the material the second light-shielding film 52 in this embodiment have conductivity, such as conductive ink, or doping the material with conductive particles.

As mentioned above, in the embodiment of the present application, the rigid support sub-layer 11 and the flexible support sub-layer 12 sequentially laminated are used as the composite support layer 10 to be disposed on one side of the backplate 20 away from the display panel 30, wherein the rigid support sub-layer 11 can serve a good supporting function for the backplate 20 and the display panel 30, while the flexible support sub-layer 12 can improve flexibility of the display device so as to improve bending performance of the display device. Further, the material of the rigid support sub-layer 11 includes polymethyl methacrylate, the material of the flexible support sub-layer 12 includes polycarbonate, the density of polymethyl methacrylate and the density of polycarbonate are both very small and less than the density of stainless steel, the density of titanium alloy, and the density of carbon fiber material, etc., thereby effectively reducing the weight of the composite support layer 10 and realizing weight reduction of the display device. Further, in the embodiment of the present application, openings 13 may be defined on the portion of the composite support layer 10 located in the bending region 101 to further improve the bending performance of the composite support layer 10, that is, to improve the bending performance of the display device. In addition, a light-shielding film having conductivity may be disposed on the one side of the rigid support sub-layer 11 away from the flexible support sub-layer 12 and on the one side of the flexible support sub-layer 12 away from the rigid support sub-layer 11, so that the composite support layer 10 provided in the embodiment of the present application has functions of light shielding and electromagnetic shielding to improve the display effect, stability, and yield of the display device.

In addition, an embodiment of the present application also provides a method for fabricating the display device described in the above-mentioned embodiments, please refer to FIG. 1, FIG. 6, and FIG. 8, the method includes following steps:
the polymethyl methacrylate and polycarbonate are co-extruded into a laminating die, hot-pressed, cooled, and shaped to form a master plate, and then cut by laser to obtain a composite support layer 10. Wherein the polymethyl methacrylate and polycarbonate will be formed in layers during a film formation process, the polymethyl methacrylate forms the rigid support sub-layer 11, the polycarbonate forms the flexible support sub-layer 12, and the rigid support sub-layer 11 is laminated with a flexible support sub-layer 12 to form a composite support layer 10.

The thickness of the rigid support sub-layer 11 is less than the thickness of the flexible support sub-layer 12. Optionally, the ratio of the thickness of the flexible support sub-layer 12 to the thickness of the rigid support sub-layer 11 is greater than or equal to 3:2, and less than or equal to 4:1, and the thickness of the composite support layer 10 is greater than or equal to 0.2 mm, and less than or equal to 0.25 mm.

In an embodiment of the present application, metal or metal oxide may be evaporated on a side surface of the rigid support sub-layer 11 away from the flexible support sub-layer 12 and on a side surface of the flexible support sub-layer 12 away from the rigid support sub-layer 11 to form the first metal shielding film 41 located on the one side of the rigid support sub-layer 11 away from the flexible support sub-layer 12 and to form the second metal shielding film 42 located on the one side of the flexible support sub-layer 12 away from the rigid support sub-layer 11.

In another embodiment of the present application, black ink may be printed or black adhesive may be coated on the side surface of the rigid support sub-layer 11 away from the flexible support sub-layer 12 and on the side surface of the flexible support sub-layer 12 away from the flexible support sub-layer 11, so as to form the first light-shielding film 51 on the one side of the rigid support sub-layer 11 away from the flexible support sub-layer 12 and to form the second light-shielding film 52 on the one side of the flexible support sub-layer 12 away from the rigid support sub-layer 11.

Optionally, the material of the first light-shielding film 51 and the material of the second light-shielding film 52 may have conductivity, so that the first light-shielding film 51 and the second light-shielding film 52 also have the function of the electromagnetic shielding.

The display panel 30 and the backplate 20 are provided, wherein the display panel may be an organic light-emitting diode (OLED) display panel, and a material of the backplate 20 may include organic materials such as polyimide.

The backplate 20 is attached to one side of the display panel 30 away from the display surface, and then the composite support layer 10 is attached to the one side of the backplate 20 away from the display panel 30, and the rigid support sub-layer 11 is disposed between the flexible support sub-layer 12 and the backplate 20.

To sum up, in the embodiment of the present application, the rigid support sub-layer 11 and the flexible support sub-layer 12 sequentially laminated are used as the composite support layer 10 to be disposed on the one side of the backplate 20 away from the display panel 30, wherein the rigid support sub-layer 11 can serve a good supporting function for the backplate 20 and the display panel 30, and the flexible support sub-layer 12 can improve the flexibility of the display device so as to improve the bending performance of the display device. Further, the material of the rigid support sub-layer 11 includes polymethyl methacrylate, the material of the flexible support sub-layer 12 includes polycarbonate, and the density of polymethyl methacrylate and the density of polycarbonate are both very small and less than the density of stainless steel, the density of titanium alloy, and the density of carbon fiber material, etc., thereby effectively reducing the weight of the composite support layer 10 and realizing weight reduction of the display device.

In the foregoing embodiments, the description of the embodiments has their own particular emphasis respectively, and as for a part which is not described in detail in a certain embodiment, reference can be made to the related description in other embodiments.

The display device provided by the embodiments of the present application are described in detail above. Specific examples are utilized in the present disclosure to explain a principle and implementations of the present application. The description of the foregoing embodiments is merely used to help understand the technical solution and a main idea of the present application. Those ordinarily skilled in the art shall appreciate that they still can modify the technical solutions recited in the foregoing respective embodiments or make equivalent substitutions for a part of technical features therein; and these modifications or substitutions will not render the essence of the corresponding technical solutions to go beyond the spirit and scope of the technical solutions in the respective embodiments of the present application.

1. A display device, comprising:
a display panel;
a backplate disposed on one side of the display panel;
a composite support layer disposed on one side of the backplate away from the display panel, the composite support layer comprising a rigid support sub-layer and a flexible support sub-layer sequentially laminated;
wherein a material of the rigid support sub-layer comprises polymethyl methacrylate, and a material of the flexible support sub-layer comprises polycarbonate.

2. The display device as claimed in claim 1, wherein an elastic modulus of the rigid support sub-layer is greater than an elastic modulus of the flexible support sub-layer.

3. The display device as claimed in claim 1, wherein the display device further comprises a bending region, and the composite support layer further comprises a plurality of openings defined in the bending region.

4. The display device as claimed in claim 3, wherein the openings penetrate at least one of the rigid support sub-layer and the flexible support sub-layer.

5. The display device as claimed in claim 4, wherein the plurality of openings comprise first openings defined in the rigid support sub-layer and second openings defined in the flexible support sub-layer, and the first openings and the second openings are arranged in alignment or staggered.

6. The display device as claimed in claim 3, wherein each of the openings extends along a first direction and is distributed in the bending region in an elongated shape, wherein the display device further comprises a non-bending region adjacent to the bending region, and an included angle between the first direction and a direction of the bending region pointing to the non-bending region is greater than or equal to 0°, and less than or equal to 90°.

7. The display device as claimed in claim 6, wherein the composite support layer further comprises a plurality of opening groups arranged along a second direction, and each of the opening groups comprises the plurality of openings arranged along the first direction, the second direction is perpendicular to the first direction, and the openings in one of the opening groups are arranged in a staggered manner with the openings in an adjacent one of the opening groups.

8. The display device as claimed in claim 1, wherein the display device further comprises a light-transmitting region, and a photosensitive device disposed in the light-transmitting region, the photosensitive device is disposed on one side of the composite support layer away from the backplate, and an orthographic projection of the photosensitive device on the backplate is located within a coverage of an orthographic projection of the composite support layer on the backplate.

9. The display device as claimed in claim 8, wherein a phase difference of the composite support layer is less than or equal to 50 nm, and a light transmittance rate of the composite support layer is greater than or equal to 90%.

10. The display device as claimed in claim 8, wherein the composite support layer further comprises a first metal shielding film disposed on one side of the rigid support sub-layer away from the flexible support sub-layer, and a second metal shielding film disposed on one side of the flexible support sub-layer away from the rigid support sub-layer, wherein the first metal shielding film and the second metal shielding film are both defined with first light-transmitting holes in the light-transmitting region.

11. The display device as claimed in claim 810, wherein the composite support layer further comprises a first light-shielding film disposed on one side of the rigid support sub-layer away from the flexible support sub-layer, and a second light-shielding film disposed on one side of the flexible support sub-layer away from the rigid support sub-layer, wherein the first light-shielding film and the second light-shielding film are both defined with second light-transmitting holes in the light-transmitting region.

12. The display device as claimed in claim 11, wherein a material of the first light-shielding film and a material of the second light-shielding film both have conductivity.

13. The display device as claimed in claim 1, wherein the rigid support sub-layer is located between the flexible support sub-layer and the backplate, and a ratio of a thickness of the flexible support sub-layer to a thickness of the rigid support sub-layer is greater than or equal to 3:2 and less than or equal to 4:1.

14. A display device comprising:
a display panel;
a backplate disposed on one side of the display panel;
a composite support layer disposed on one side of the backplate away from the display panel, the composite support layer comprising a rigid support sub-layer and a flexible support sub-layer sequentially laminated, and an elastic modulus of the rigid support sub-layer being greater than an elastic modulus of the flexible support sub-layer;
wherein a material of the rigid support sub-layer comprises polymethyl methacrylate, and a material of the flexible support sub-layer comprises polycarbonate.

15. The display device as claimed in claim 14, wherein the display device further comprises a bending region, and the composite support layer further comprises a plurality of openings defined in the bending region.

16. The display device as claimed in claim 14, wherein the display device further comprises a light-transmitting region and a photosensitive device disposed in the light-transmitting region, the photosensitive device is disposed on one side of the composite support layer away from the backplate, and an orthographic projection of the photosensitive device on the backplate is located within a coverage of an orthographic projection of the composite support layer on the backplate.

17. The display device as claimed in claim 16, wherein a phase difference of the composite support layer is less than or equal to 50 nm, and a light transmittance rate of the composite support layer is greater than or equal to 90%.

18. The display device as claimed in claim 16, wherein the composite support layer further comprises a first metal shielding film disposed on one side of the rigid support sub-layer away from the flexible support sub-layer, and a second metal shielding film disposed on one side of the flexible support sub-layer away from the rigid support sub-layer, wherein the first metal shielding film and the second metal shielding film are both defined with first light-transmitting holes in the light-transmitting region.

19. The display device as claimed in claim 18, wherein the composite support layer further comprises a first light-shielding film disposed on one side of the rigid support sub-layer away from the flexible support sub-layer, and a second light-shielding film disposed on one side of the flexible support sub-layer away from the rigid support sub-layer, wherein the first light-shielding film and the second light-shielding film are both defined with second light-transmitting holes in the light-transmitting region.

20. The display device as claimed in claim 19, wherein a material of the first light-shielding film and a material of the second light-shielding film both have conductivity.
